(19) United States
(12) Patent Application Publication
(10) Pub. No.: US 2008/0007311 A1
(43) Pub. Date: Jan. 10, 2008

(54) Phase locked loop, phase locked loop method and semiconductor device having phase locked loop

(75) Inventor: Young-Don Choi, Anseong-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/808,053

(22) Filed: Jun. 6, 2007

(30) Foreign Application Priority Data
Jul. 10, 2006 (KR) 10-2006-0064622

(51) Int. Cl. H03L 7/06

(52) U.S. Cl. 327/156

(57) ABSTRACT

A phase locked loop (PLL) circuit may include a phase difference detecting and control signal generating portion, a voltage control oscillator, and/or an initial control voltage generating portion. The phase difference detecting and control signal generating portion may be configured to detect a phase difference between an input clock signal and an output clock signal to control a voltage level of a control signal. The voltage control oscillator may be configured to vary a frequency of the output clock signal in response to the voltage level of the control signal. The initial control voltage generating portion may be configured to receive the input clock signal, calculate a locking control voltage corresponding to the input clock signal, and/or cause the voltage level of the control signal to become a level of the locking control voltage from power up of the phase locked loop circuit.

### PRIORITY STATEMENT

This application claims the benefit of priority to Korean Patent Application No. 10-2006-0064622, filed Jul. 10, 2006, in the Korean Intellectual Property Office, the entire contents of which are hereby incorporated herein by reference in their entirety.

### BACKGROUND

1. Field

Example embodiments relate to a phase locked loop and, for example, to a phase locked loop, a phase locked loop method, and/or a semiconductor device having a phase locked loop in which a locking time is reduced.

2. Description of Related Art

A conventional phase locked loop (PLL) circuit may include a voltage control oscillator and/or perform an operation for locking a phase of an output clock signal with a phase of an input signal while gradually increasing a voltage level of a control signal applied to the voltage control oscillator, e.g., gradually increasing a frequency of an output clock signal. Accordingly, the conventional PLL circuit may have a long locking time, which is a time until a phase of the output clock signal is locked with a phase of the input clock signal.

FIG. 1 is a block diagram illustrating a conventional PLL circuit. The conventional PLL circuit of FIG. 1 may include a phase difference detector 10, a charge pump 12, a loop filter 14, a voltage control oscillator 16, and/or a divider 18.

Functions of the components of FIG. 1 are explained below.

The phase difference detector 10 detects a phase difference between an input clock signal ICK and an output clock signal OCK1 to generate an up signal UP if a phase of the input clock signal ICK precedes a phase of the output clock signal or to generate a down signal DN if a phase of the output clock signal precedes a phase of the input clock signal ICK. The charge pump 12 performs a pumping operation, and/or the charge pump 12 may raise a voltage level of a control voltage Vc in response to the up signal UP or decrease the voltage level of the control voltage Vc in response to the down signal DN. The loop filter 14 filters the control voltage Vc to generate a filtered control signal RVc. The voltage control oscillator 16 adjusts frequencies of n output clock signals OCK1 to OCKn in response to the filtered control signal RVc. For example, the n output clock signals OCK1 to OCKn may have different phases, have the same phase difference therebetween, and/or the same frequency. The output clock signal OCK1 may have the same phase as the input clock signal ICK. The divider 18 divides the output clock signal OCK1 to generate a divided output clock signal DCK. The divider 18 is configured to cause the frequency of the output clock signal OCK1 to be the same as the frequency of the input clock signal ICK if the frequency of the output clock signal OCK is higher than the frequency of the input clock signal ICK. The divider 18 may not be an essential component of the conventional PLL circuit.

FIG. 2 is an example graph illustrating a variation of the frequency of the output clock signal OCK1 with respect to the voltage level of the filtered control signal RVc in the conventional PLL circuit of FIG. 1.

As can be seen in FIG. 2, as the voltage level of the filtered control signal RVc increases, the frequency of the output clock signal OCK1 increases relatively slowly, and if the voltage level of the control signal RVc reaches a locking control voltage Vco, the phase of the output clock signal OCK1 and the phase of the input clock signal ICK may be locked.

The PLL circuit of FIG. 1 increases the voltage level of the filtered control signal RVc relatively slowly from a lower voltage (e.g., 0 volts) and operates until the voltage level of the filtered control signal RVc reaches the locking control voltage Vco. Accordingly, a time spent until the voltage level of the filtered control signal RVc reaches the locking control voltage Vco, i.e., the locking time, may be longer.

As the locking time is longer, power consumption of the PLL circuit during the locking time becomes larger.

The PLL circuit may be included in a data transceiving device to generate the output clock signal OCK1, synchronized with the input clock signal ICK, and the output clock signals OCK2 to OCKn, which have different phases from the output clock signal OCK1 and the same frequency as the output clock signal OCK1. The data transceiving device receives data in response to the n output clock signals OCK1 to OCKn if data are input or output in response to the n output clock signals OCK1 to OCKn. However, if the locking time is longer, data may not be exactly received or output because data transmission is performed in a state in which the phase of the input clock signal ICK and the phase of the n output clock signals OCK1 to OCKn are not locked.

Conventional PLL circuits having various configurations directed to the above described problem have been suggested.

For example, another conventional PLL circuit includes a discharge circuit and/or a frequency detecting circuit in addition to the configuration of the conventional PLL circuit of FIG. 1. Another conventional PLL circuit causes the voltage level of the filtered control signal RVc to become an upper voltage (e.g., a power voltage) level with the loop filter at the initial stage, slowly drops the voltage level of the filtered control signal RVc with the discharge circuit, and stops the discharging operation of the discharge circuit if the frequency detecting circuit determines that the frequency of the output clock signal OCK1 is the same as the frequency of the input clock signal ICK, and performs the same operation as the conventional PLL circuit of FIG. 1. For example, this conventional PLL circuit detects if the frequency of the output clock signal OCK1 is identical to the frequency of the input clock signal ICK while lowering, relatively slowly, the frequency of the output clock signal OCK1 before the PLL circuit of FIG. 1 performs an operation for locking the phase of the input clock signal ICK and the phase of the output clock signal OCK1. Accordingly, this conventional PLL circuit may reduce the locking time compared to the conventional PLL circuit of FIG. 1.

However, even though this conventional PLL circuit has the reduced locking time compared to the conventional PLL circuit of FIG. 1, this conventional PLL circuit may have a limitation in minimizing the locking time because the voltage level of the control signal RVc is detected when the frequency of the input clock signal ICK is identical to the frequency of the output clock signal OCK1 while slowly dropping the voltage level of the filtered control signal RVc with the discharge circuit during the initialization period.

### SUMMARY

Example embodiments may provide a phase locked loop (PLL) circuit in which the clocking time for locking a phase of an input clock signal and a phase of an output clock signal may be reduced.

Example embodiments may provide a phase locked loop (PLL) method in which the clocking time for locking a phase of an input clock signal and a phase of an output clock signal may be reduced.

Example embodiments may provide a semiconductor device including a phase locked loop (PLL) circuit in which the clocking time for locking a phase of an input clock signal and a phase of an output clock signal may be reduced.

According to an example embodiment, a phase locked loop (PLL) circuit may include a phase difference detecting and control signal generating portion, a voltage control oscillator, and/or an initial control voltage generating portion. The phase difference detecting and control signal generating portion may be configured to detect a phase difference between an input clock signal and an output clock signal to control a voltage level of a control signal. The voltage control oscillator may be configured to vary a frequency of the output clock signal in response to the voltage level of the control signal. The initial control voltage generating portion may be configured to receive the input clock signal, calculate a locking control voltage corresponding to the input clock signal, and/or cause the voltage level of the control signal to become a level of the locking control voltage for a period of time.

According to an example embodiment, the period of time may be a period of time from power up.

According to an example embodiment, a phase locked loop (PLL) circuit may include a phase difference detecting and control signal generating portion, a voltage control oscillator, and/or an initial control voltage generating portion. The phase difference detecting and control signal generating portion may be configured to detect a phase difference between an input clock signal and an output clock signal to control a voltage level of a control signal. The voltage control oscillator may be configured to vary a frequency of the output clock signal in response to the voltage level of the control signal. The initial control voltage generating portion may be configured to receive the input clock signal, calculate a locking control voltage corresponding to the input clock signal, and cause a voltage level of the control signal to become a level of the locking control voltage until the voltage level of the control signal reaches a threshold.

According to an example embodiment, a semiconductor device may include the phase locked loop (PLL) circuit. The phase locked loop (PLL) circuit may be configured to generate a plurality of output clock signals which have different phases, the same phase difference therebetween, and the same frequency based on the control signal. A data I/O portion may be configured to receive data applied externally in response to the plurality of output clock signals and output data generated internally to an external portion

According to an example embodiment, the initial control voltage generating portion may be configured to calculate the locking control voltage based on a number of times that a first clock signal is generated in response to an upper locking control voltage which is an upper voltage level of the control signal and a number of times that the input clock signal is generated during a same time period.

According to an example embodiment, the initial control voltage generating portion may be configured to generate a first clock signal in response to an upper locking control voltage which is an upper voltage level of the control signal, a second clock signal in response to a lower locking control voltage which is a lower voltage level of the control signal, and/or the locking control voltage based on a number of times that the first clock signal is generated and a number of times that the input clock signal is generated during a time period corresponding to a period of the second clock signal.

According to an example embodiment, the initial control voltage generating portion may include a voltage divider, a first clock signal generator, a second clock signal generator, and/or a code value generator. The voltage divider may be configured to divide a power supply voltage to generate a plurality of divided voltages and select one of the plurality of divided voltages in response to a code value as the locking control voltage. The first clock signal generator may be configured to generate the first clock signal in response to the upper locking control voltage which is the highest voltage of the plurality of divided voltages. The second clock signal generator may be configured to generate the second clock signal in response to the lower locking control voltage which is the lowest voltage of the plurality of divided voltages. The code value generator may be configured to generate the code value based on the number of times that the first clock signal is generated and the number of times that the input clock signal is generated during the time period corresponding to the period of the second clock signal.

According to an example embodiment, the code value generator may include a divider, a first counter, a second counter, and/or a calculator. The divider may be configured to divide the second clock signal to generate a divided second clock signal. The first counter may be configured to generate a first count of a number of times the first clock signal is generated in response to the divided second clock signal. The second counter may be configured to generate a second count of a number of times the input clock signal is generated in response to the divided second clock signal. The calculator may be configured to calculate and output the code value based on the first count and the second count in response to the divided second clock signal.

According to an example embodiment, the calculator may be configured to generate a switching control signal in response to a falling transition of the divided second clock signal, and/or the initial control voltage generating portion may further includes a switch configured to generate the locking control voltage in response to the switching control signal.

According to an example embodiment, the voltage control oscillator may include a plurality of first inverters which are dependently connected in the form of a ring. Each of the first and second clock signal generators may include a plurality of second inverters which are equal in number to the plurality of first inverters, and/or the plurality of first inverters and the plurality of second inverters have a same delay time.

According to an example embodiment, the voltage control oscillator may include a plurality of first inverters which are dependently connected in the form of a ring. Each of the first and second clock signal generators may include a plurality of second inverters which are different in number from the plurality of first inverters, and/or the plurality of first inverters and the plurality of second inverters have a same delay time.

According to an example embodiment, the phase locked loop circuit (PLL) may further include a divider. The divider may be configured to divide the output clock signal output from the voltage control oscillator to generate at least one divided output clock signal. The phase difference detecting and control signal generating portion may be configured to detect the phase difference between the input clock signal and the at least one divided output clock signal to control the voltage level of the control signal.

According to an example embodiment, the phase difference detecting and control signal generating portion may include a phase difference detector and/or a charge pump and loop filter. The phase difference detector may be configured to detect the phase difference between the input clock signal and the at least one divided output clock signal to generate up and down signals. The charge pump and loop filter may be configured to perform an up counting operation to raise the voltage level of the control signal in response to the up signal and perform a down counting operation to lower the voltage level of the control signal in response to the down signal.

According to an example embodiment, the phase difference detecting and control signal generating portion may include a phase difference detector, a counter, and/or a digital-to-analog (DA) converter. The phase difference detector may be configured to detect the phase difference between the input clock signal and the divided output clock signal to generate up and down signals. The counter may be configured to generate a digital counting signal by performing an up counting operation in response to the up signal and performing a down counting operation in response to the down signal. The digital-to-analog (DA) converter and loop filter may be configured to control the voltage level of the control signal in response to the digital counting signal.

According to an example embodiment, a phase locked loop (PLL) method may include detecting a phase difference between an input clock signal and an output clock signal to control a voltage level of a control signal. A frequency of the output clock signal may be varied in response to the voltage level of the control signal. The input clock signal may be received, a locking control voltage corresponding to the input clock signal may be calculated, and/or the voltage level of the control signal may be caused to become a level of the locking control voltage for a period of time.

According to an example embodiment, a phase locked loop (PLL) method may include detecting a phase difference between an input clock signal and an output clock signal to control a voltage level of a control signal. A frequency of the output clock signal may be varied in response to the voltage level of the control signal. The input clock signal may be received, a locking control voltage corresponding to the input clock signal may be calculated, and/or the voltage level of the control signal may be caused to become a level of the locking control voltage until the voltage level of the control signal reaches a threshold.

According to an example embodiment, calculating the locking control voltage step may include calculating the locking control voltage based on a number of times that a first clock signal is generated in response to an upper locking control voltage which is an upper voltage level of the control signal and a number of times that the input clock signal is generated during a same time period.

According to an example embodiment, the calculating the locking control voltage step may include generating a first clock signal in response to an upper locking control voltage which is an upper voltage level of the control signal. A second clock signal may be generated in response to a lower locking control voltage which is a lower voltage level of the control signal; The locking control voltage may be generated based on a number of times that the first clock signal is generated and a number of times that the input clock signal is generated during a time period corresponding to a period of the second clock signal.

According to an example embodiment the calculating the locking control voltage step further may include dividing a power supply voltage to generate a plurality of divided voltages and selecting one of the plurality of divided voltage in response to a code value as the locking control voltage. The first clock signal may be generated in response to the upper locking control voltage which is the highest voltage among the plurality of divided voltages. The second clock signal may be generated in response to the lower locking control voltage which is the lowest voltage among the plurality of divided voltages. The code value may be generated based on the number of times that the first clock signal is generated and the number of times that the input clock signal is generated during the time period corresponding to the period of the second clock signal.

According to an example embodiment, the generating the code value step may include dividing the second clock signal to generate a divided second clock signal. A counting operation may be performed to generate a first count of a number of times the first clock signal is generated in response to the divided second clock signal. A counting operation may be performed to generate a second count of a number of times the input clock signal is generated in response to the divided second clock signal. The code value may be calculated and output based on the first count and the second count in response to the divided second clock signal.

### BRIEF DESCRIPTION OF THE DRAWINGS

The above and/or other features and/or other aspects and advantages will become more apparent and more readily appreciated from the following detailed description of example embodiments taken in conjunction with the accompanying drawings of which:

FIG. 1 is a block diagram illustrating a conventional PLL circuit;

FIG. 2 is an example graph illustrating a variation of a frequency of an output clock signal OCK1 with respect to a voltage level of a filtered control signal RVc in the conventional PLL circuit of FIG. 1;

FIG. 3 is a block diagram illustrating a PLL circuit according to an example embodiment;

FIG. 4 is an example graph illustrating a method for calculating a control voltage of an initial control voltage generator of the PLL circuit according to an example embodiment;

FIG. 5 is a circuit diagram illustrating a voltage control oscillator according to an example embodiment;

FIG. 6 is a block diagram illustrating an initial control voltage generator of the PLL circuit according to an example embodiment;

FIG. 7 is a circuit diagram illustrating a voltage divider of the initial control voltage generator of FIG. 6;

FIG. 8 is a circuit diagram illustrating a first (or second) clock signal generator of the initial control voltage generator of FIG. 6;

FIG. 9 is a circuit diagram illustrating a code value generator of the initial control voltage generator of FIG. 6;

FIG. 10 is an example timing diagram illustrating an operation of the code value generator of FIG. 9;

FIG. 11 is a circuit diagram illustrating a phase difference detector of the PLL circuit of FIG. 3;

FIG. 12 is a circuit diagram illustrating a charge pump and the loop filter of the PLL circuit of FIG. 3;

FIG. 13 is a circuit diagram illustrating a divider of the PLL circuit of an example embodiment in FIG. 3;

FIG. 14 is a block diagram illustrating a PLL circuit according to another example embodiment;

FIG. 15 is a circuit diagram illustrating a DA converter and the loop filter of the PLL circuit of the embodiment of FIG. 14;

FIG. 16 is a block diagram illustrating a semiconductor device according to an example embodiment; and

FIG. 17 is an example timing diagram illustrating operations of the PLL of a control signal generating portion of the semiconductor device of the embodiment of FIG. 16.

### DETAILED DESCRIPTION OF EXAMPLE EMBODIMENTS

Example embodiments will now be described more fully hereinafter with reference to the accompanying drawings. Embodiments may, however, be in many different forms and should not be construed as limited to the example embodiments set forth herein. Rather, these example embodiments are provided so that this disclosure will be thorough and complete, and will fully convey the scope to those skilled in the art. In the drawings, the thickness of layers and regions are exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

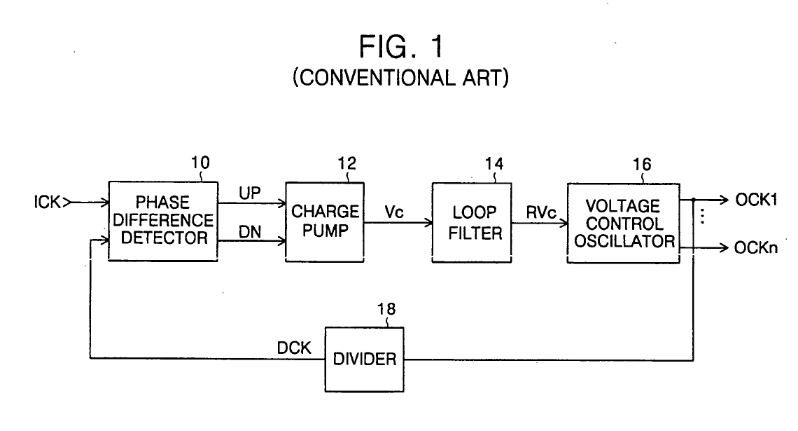

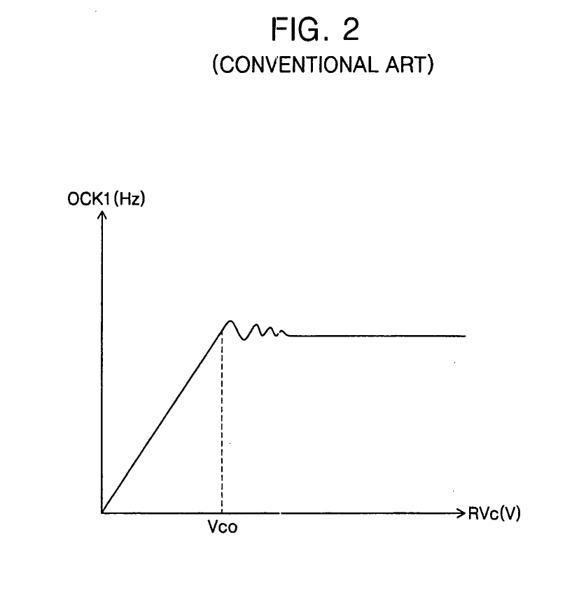

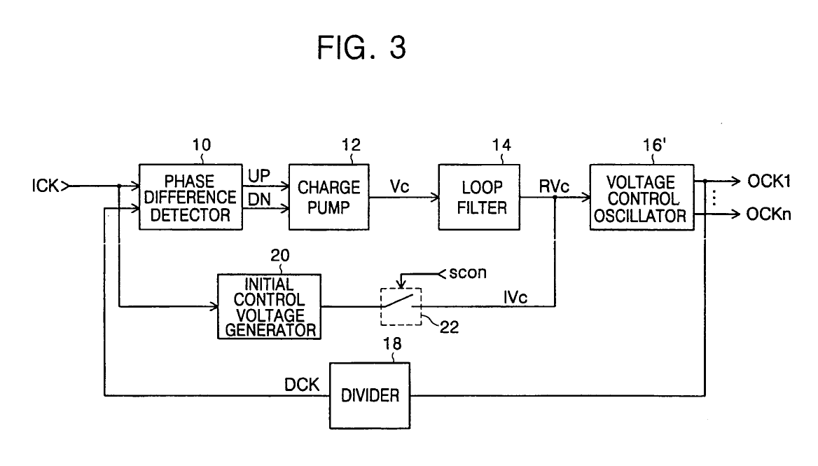

FIG. 3 is a block diagram illustrating a PLL circuit according to an example embodiment. The PLL circuit of FIG. 3 may include the components of to the PLL circuit of FIG. 1, however, the PLL circuit of FIG. 3 may further include an initial control voltage generator 20 and/or a switch 22.

Functions of the components of FIG. 3 are explained below, with particular attention given to the functions of the initial control voltage generator 20 and/or the switch 22. Unless specifically noted, the structure and operation of those components in FIG. 3 common to the PLL circuit of FIG. 1 are the same as described with respect to FIG. 1; and may not be described in detail below for the sake of brevity.

The initial control voltage generator 20 may receive the input clock signal ICK to generate an initial control voltage IVc corresponding to the input clock signal ICK at an initial stage, e.g., for a period of time from power up. For example, the initial control voltage IVc corresponding to the input clock signal ICK may be referred to as a control voltage of the filtered control signal RVc applied to the voltage control oscillator 16′ if the phase of the input clock signal ICK and the phase of the output clock signal OCK1 are locked. The switch 22 may be turned on in response to a switching control signal scon to transmit the initial control voltage IVc at the initial stage and/or may be turned off.

Even though not shown, the PLL circuit of example embodiments may include another switch (not shown) between the loop filter 14 and a node receiving output of the switch 22. The switch 22 may be connected to the output terminal of the charge pump 12 instead of the output terminal of the loop filter 14 to thereby control the control voltage Vc. The PLL circuit of example embodiments may be configured not to apply an electrical power to the phase difference detector 10, the charge pump 12, and/or the loop filter 14 until at the initial stage the initial control voltage generator 20 operates and the switch 22 is turned on so that the initial control voltage IVc may be transmitted. For example, the PLL circuit of example embodiments may be configured such that a power supply voltage is not applied to the phase difference detector 10, the charge pump 12, and the loop filter 14 until the switch 22 is turned on in response to the switching control signal SCON, and the power supply voltage may be applied to the phase difference detector 10, the charge pump 12, and the loop filter 14 when the switch 22 is turned off in response to the switching control signal scon.

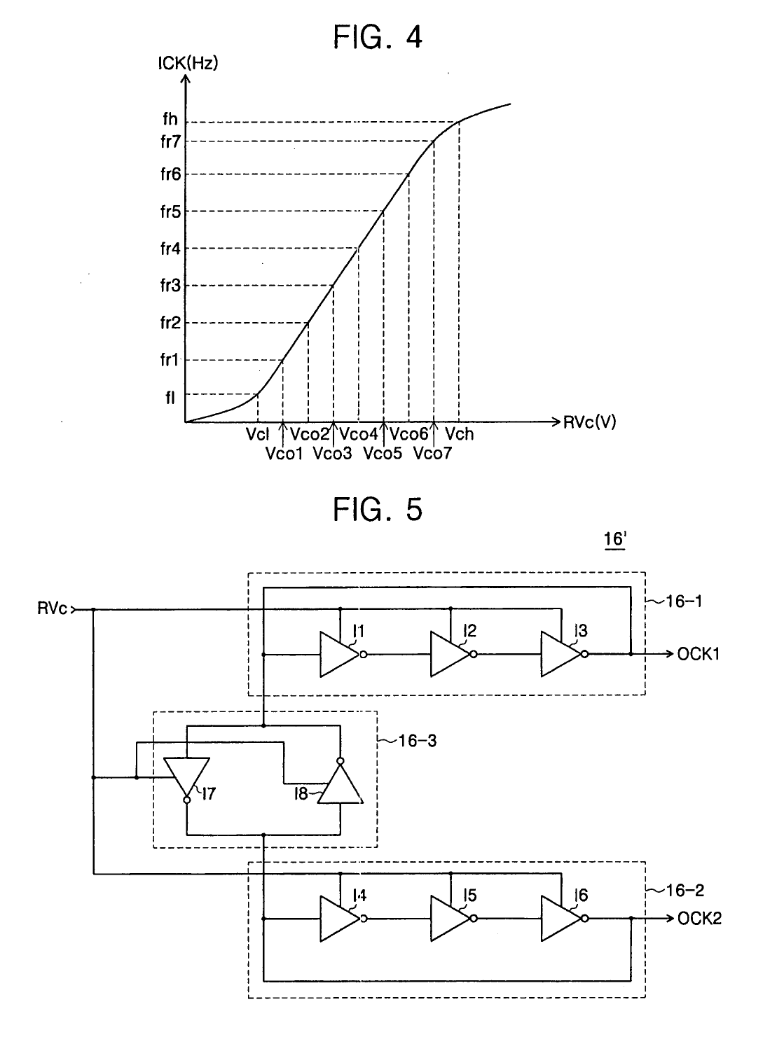

FIG. 4 is an example graph illustrating a method for calculating the initial control voltage IVc of the initial control voltage generator 20 of the PLL circuit according to an example embodiment. For example, Vcl denotes a lower locking control voltage, Vch denotes an upper locking control voltage, Vco1 to Vco7 denote calculated locking control voltages, fl denotes a lower frequency corresponding to the lower locking control voltage Vcl, fh denotes an upper frequency corresponding to the upper locking control voltage Vch, and/or fr1 to fr7 denote frequencies of the input clock signal respectively corresponding to the calculated locking voltages Vco1 to Vco7. In FIG. 4, the initial control voltage IVc is adjusted in 9 steps, however, example embodiments are not limited thereto and the control voltage may be adjusted in more or less than 9 steps.

The initial control voltage generator 20 of the PLL circuit according to an example embodiment may calculate and/or generate the locking control voltages Vch, Vco7 to Vco1 and Vcl, which respectively correspond to frequencies flh, fr7 to fr1 and fl of the input clock signal ICK, by using a first clock signal CLK1 having the upper frequency fh corresponding to the upper locking control voltage Vch and a second clock signal CLK2 having the lower frequency fl corresponding to the lower locking control voltage Vcl. For example, if the frequency of the input clock signal ICK is fr1, the locking control voltage Vc01 may be generated, and if the frequency of the input clock signal ICK is fr6, the locking control voltage Vc06 may be generated.

The frequency of the input clock signal ICK may be calculated by comparing the number of times that the first clock signal CLK1 having the upper frequency flh is generated and the number of times that the input clock signal ICK is generated while the second clock signal CLK2 having the lower frequency fl is generated once. For example, if the locking control voltages Vch, Vco7 to Vco1 and Vcl are generated in response to a 9-bit code value and the first clock signal CLK1 having the upper frequency fh is generated 9 times while the second clock signal CLK2 having the lower frequency fl is generated once, the locking control voltage Vco7 corresponding to the fr7 may be output if the input clock signal ICK is generated 8 times while the second clock signal CLK2 having the lower frequency fl is generated once. AS another example the locking control voltage Vco5 corresponding to the frequency fr5 may be output if the input clock signal ICK is generated 6 times.

Accordingly, the initial control voltage generator 20 of example embodiments may calculate the initial control voltage IVc of the filter control signal RVc corresponding to the frequency of the input clock signal ICK by comparing the number of times that the input clock signal ICK is generated and the number of times that the first clock signal CLK1 having the upper frequency fh is generated during a time period corresponding to a period of the second clock signal CLK2 having the lower frequency fl, for example, the same time period as the period of the second clock signal CLK2 having the lower frequency or an integer multiple of the period of the second clock signal CLK2 having the lower frequency.

FIG. 5 is a circuit diagram illustrating the voltage control oscillator 16′ according to an example embodiment. The voltage control oscillator of FIG. 5 may include a first ring oscillator 16-1 including three inverters I1 to I3 configured in the form of a ring, a second ring oscillator 16-2 including three inverters I4 to I6 configured in the form of a ring, and/or a latch 16-3 including inverters I7 and I8. FIG. 5 illustrates an example embodiment in which the voltage control oscillator 16′ includes first and second ring oscillators 16-1 and 16-2 and/or a latch 16-3, however, example embodiments are not limited thereto and the voltage control oscillator 16′ of example embodiments may include any number of first and second ring oscillators with corresponding latches. FIG. 5 shows ring oscillators 16-1 and 16-2 including 3 inverters I1-13 and I4-16, however, example embodiments are not limited thereto, and ring oscillators of example embodiments may include any odd number of inverters.

Functions of the components of FIG. 5 are explained below.

The first ring oscillator 16-1 may adjust the frequency of the output clock signal OCK1 in response to the level of the filtered control signal RVc, and/or the second ring oscillator 16-2 may adjust the frequency of the output clock signal OCK2 in response to the level of the filtered control signal RVc to thereby have the inverted phase. For example, the filtered control signal RVc may be a supply voltage for each of the inverters I1-I3 in the first ring oscillator 16-1 and each of the inverters I4-I6 in the second ring oscillator 16-2. As the level of the supply voltage for the inverters I1-I3 and I4-I6 increases, for example, a the level the filtered control signal RVc increases, the frequency of the output clock signal OCK1 and OCK2 may increase, and a delay time of the first and second ring oscillators 16-1 and 16-2 may decrease. On the other hand, if the level of the filtered control signal RVc is reduced, the frequencies of the output clock signals OCK1 and OCK2 may be lowered, and a delay time of the first and second ring oscillators 16-1 and 16-2 may increase. The latch 16-3 may latch the output clock signals OCK1 and OCK2. As noted above, FIG. 5 shows a voltage control oscillator 16′ including first and second ring oscillators 16-1 and 16-2 configured to output a first output clock signal and a second output clock signal. However, example embodiments are not limited thereto, and the voltage control oscillator 16′ of example embodiments may include any number of ring oscillators 16-1 to 16-n, and/or the ring oscillators 16-1 to 16-n may adjust output clock signals OCK1 to OCKn and/or corresponding latches 16-3 may be configured between each of the ring oscillators 16-1 to 16-n to latch two corresponding output clock signals from the output signals OCK1 to OCKn. For example, the n output clock signals OCK1 to OCKn may have different phases, have the same phase difference therebetween, and/or the same frequency. The output clock signal OCK1 may have the same phase as the input clock signal ICK.

If each delay time of the three inverters I1 to I3 of the voltage control oscillator 16′ of FIG. 5 is “d”, the period of the output clock signals may be “6πd”. Accordingly, the voltage control oscillator 16′ may generate the output clock signals OCK1 to OCK2 which oscillate with the frequency of 6πd. The voltage control oscillator 16′ may generate the output clock signals OCK1 and OCK2 having the same frequency as or an integer multiple of the frequency of the input clock signal ICK if the locking control voltage Vco is applied. For example, increasing the supply voltage of the three inverters I1 to I3, by increasing the level of the filtered control voltage RVc, the output cock signals OCK1 and OCK2 may be generated at an integer multiple of the frequency of the input clock signal ICK.

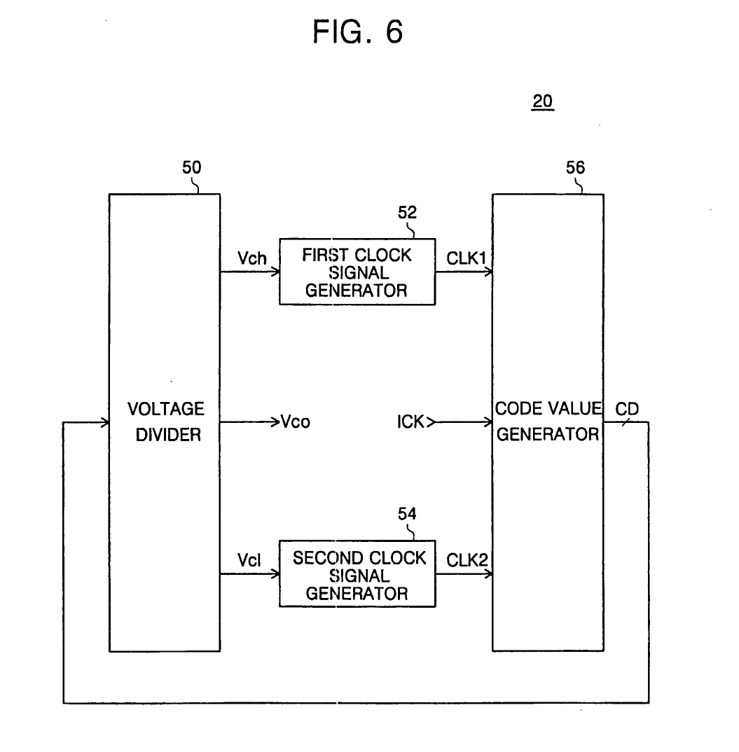

FIG. 6 is a block diagram illustrating the initial control voltage generator 20 of the PLL circuit according an example embodiment. The initial control voltage generator 20 of FIG. 6 may include a voltage divider 50, a first clock signal generator 52, a second clock signal generator 54, and/or a code value generator 56.

Functions of the components of FIG. 6 are explained below.

The voltage divider 50 may generate the upper locking control voltage Vch and the lower locking control voltage Vcl and/or generate a locking control voltage Vco in response to a code value CD. The first and second clock signal generators 52 and 54 may be realized by inverters, for example the first and second clock signal generators 52 and 54 may be realized by inverters having the same delay time as each delay time of the inverters I1 to I3 of the voltage control oscillator 16′ of FIG. 5. The first clock signal generator 52 may generate the first clock signal CLK1 having the upper frequency in response to the upper locking control voltage Vch, and/or the second clock signal generator 54 may generate the second clock signal CLK2 having the lower frequency in response to the lower locking control voltage Vcl. For example, because the upper locking control voltage Vch is greater than the lower locking control voltage Vcl, the first clock signal generator, which receives the upper locking control voltage Vch, may generate the first clock signal OCK1 with a greater frequency than that of the second clock signal OCK2 which is generated by the second clock signal generator 54 in response to lower locking control voltage Vcl. The code value generator 56 may generate the code value CD by comparing the number of times that the first clock signal CLK1 is generated and the number of times that the input clock signal ICK is generated during a time period corresponding to the period of the second clock signal CLK2. The code value may be a plural-bit digital signal and/or may be configured such that one of the plural bits is “0” and the remaining bits are “1” or one of the plural bits is “1” and the remaining bits are “0”. The generated locking control voltage Vco may become more accurate as the number of bits in the code value CD is increased. For example, the first and second clock signal generators 52 and 54 may have the same configuration as the voltage control oscillator of FIG. 5.

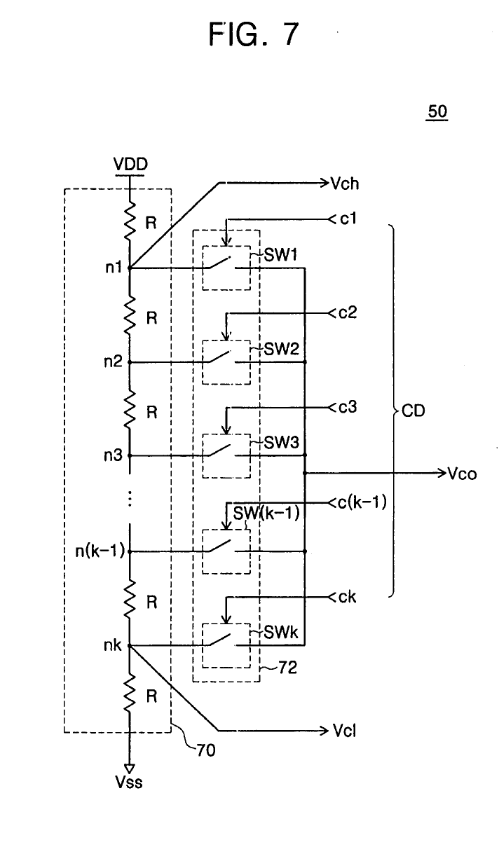

FIG. 7 is a circuit diagram illustrating a voltage divider 50 of the initial control voltage generator 20 of FIG. 6. The voltage divider of FIG. 7 may include a voltage dividing circuit 70 having (k+1) resistors R and/or a switching circuit 72 having k switches SW1 to SWk.

Functions of the components of FIG. 7 are explained below.

The (K+1) resistors R may be serially connected between a power voltage VDD and a ground voltage Vss to generate the upper locking control voltage Vch and the lower locking control voltage Vcl respectively through nodes n1 and nk and/or to generate divided voltages respectively through nodes n2 to n(k−1). The k switches SW1 to SWk may be turned on to generate the divided voltages of the nodes n1 to nk as the locking control voltage Vco in response to the respective bits c1 to ck of the code value CD.

If the k switches SW1 to SWk are respectively turned on in response to bit data of “1”, the code value CD (for example, bits c1 to ck) may preferably be configured such that one bit is “1” and the remaining bits are “0”. If the k switches SW1 to SWk are respectively turned on in response to bit data of “0” the code value CD (for example, bits c1 to ck) may preferably be configured such that one bit is “0” and the remaining bits are “1”.

For example, the code value generator 56 of FIG. 6 may generate the code value CD such that the greater the difference between the number of times that the first clock signal CLK1 is generated in response to the upper locking control voltage Vch and the number of times that the input clock signal ICK is generated while the second clock signal CLK2 is generated once in response to the lower voltage Vcl, the higher the locking control voltage Vco generated.

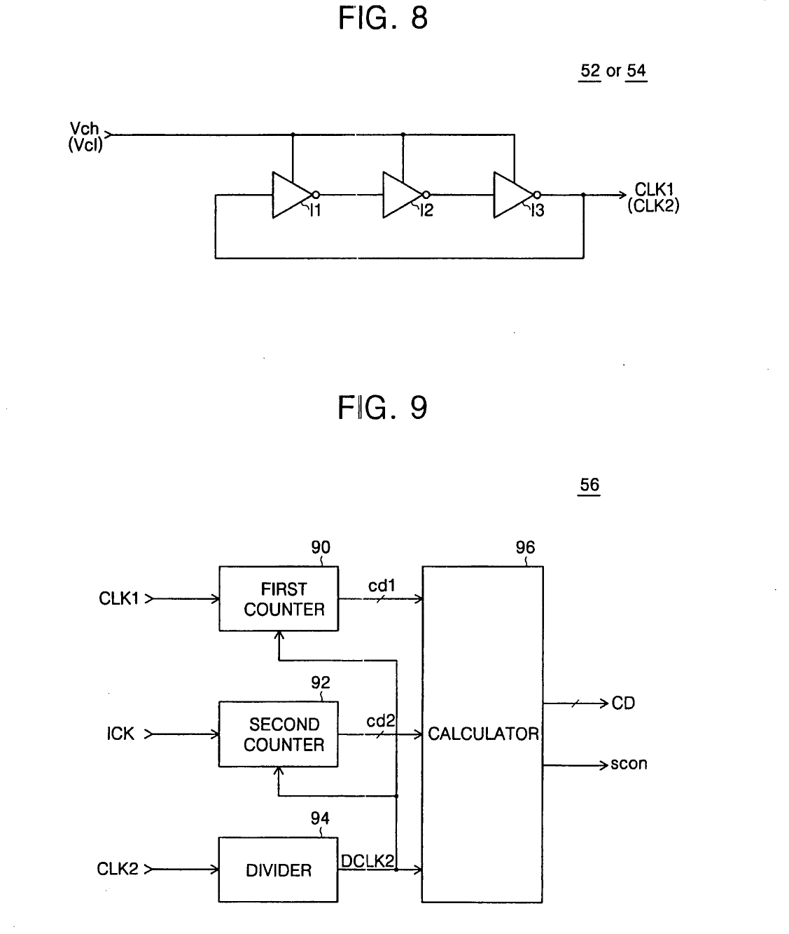

FIG. 8 is a circuit diagram illustrating the first (or second) clock signal generator 52 (or 54) of the initial control voltage generator 20 of FIG. 6. Similar to the voltage control oscillator 16′ of FIG. 5, the first (or second) clock signal generator 52 (or 54) may include three inverters I1 to I3 which are dependently connected in the form of a ring. However, example embodiments are not limited thereto, and the first (or second) clock signal generator 52 (or 54) may include any odd number of inverters which are dependently connected in the form of a ring.

The inverters I1 to I3 may preferably have the same delay time as the voltage control oscillator 16′ of FIG. 5.

The first (or second) clock signal generator 52 (or 54) of FIG. 8 may preferably be configured to generate the first (or second) clock signal CLK1 (or CLK2) having the same frequency as the first (or second) output clock signal OCK1 (or OCK2) generated by the voltage control oscillator 16′ of FIG. 5 in response to the upper (or lower) locking control voltage Vch (or Vcl). For example, as a level of a supply voltage applied to the inverters I1 to I3 of the first (or second) clock signal generator 52 (or 54) increases, for example as the level of the upper (or lower) locking control voltage Vch (or Vcl) increases, the frequency of the first (or second) clock signal CLK1 (or CLK2) may increase. On the other hand, as the level of the upper (or lower) locking control voltage Vch (or Vcl) decreases, the frequency of the first (or second) clock signal CLK1 (or CLK2) may decrease.

FIG. 9 is a circuit diagram illustrating the code value generator 56 of the initial control voltage generator 20 of FIG. 6. The code value generator 56 of FIG. 9 may include first and second counters 90 and 92, a divider 94, and/or a calculator 96.

Functions of the components of FIG. 9 are explained below.

The first counter 90 may count the number of times that the first clock signal CLK1 is generated to generate a first code value cd1 in response to a divided second clock signal DCLK2. For example, the first counter 90 may be enabled in response to the divided second clock signal DCLK2 and/or perform a counting operation to generate the first code value cd1 in response to the first clock signal CLK1. The second counter 92 may count the number of times that the input clock signal ICK is generated to generate a second code value cd2 in response to the divided second clock signal DCLK2. For example, the second counter 92 may be enabled in response to the divided second clock signal DCLK2 and/or perform a counting operation to generate the second code value cd2 in response to the input clock signal ICK. The divider 94 may divide the second clock signal CLK2 to generate the divided second clock signal DCLK2. The calculator 96 may compare the first code value cd1 and the second code value cd2 in response to the divided second clock signal DCLK2 to calculate and output the code value CD and/or to generate a switching control signal scon. For example, the calculator 96 may detect a falling transition (e.g., transition to a low level) of the divided second clock signal DCLK2 to calculate the code value CD, and/or the calculator 96 may detect a falling transition of the divided second clock signal DCLK2 to generate the switching control signal scon.

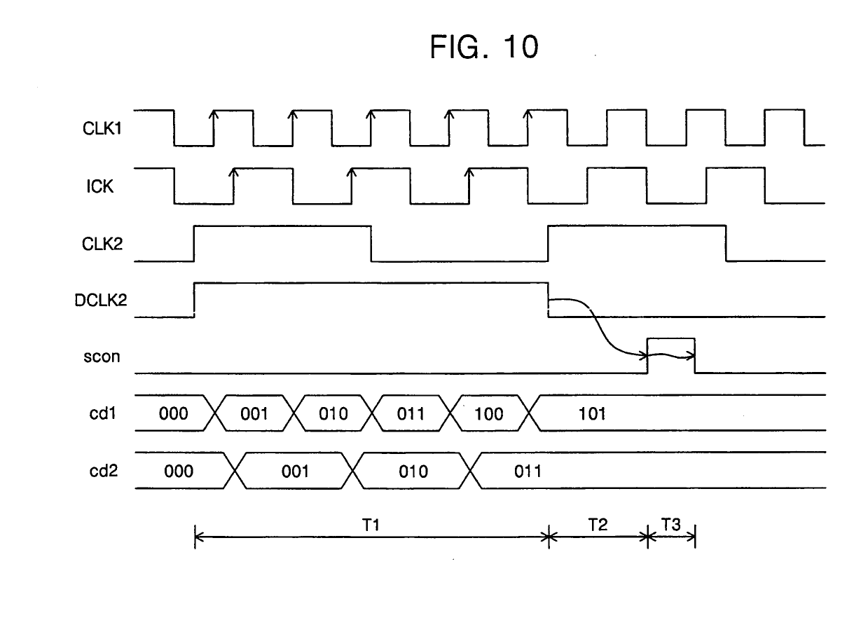

FIG. 10 is an example timing diagram illustrating an operation of the code value generator 56 of FIG. 9. For example, it may be assumed that the first and second counters 90 and 92 generate the 3-bit first and second code values cd1 and cd2, respectively, and are initialized to “000”.

The operation of the code value generator of FIG. 9 is explained below with reference to FIG. 10.

During a first time period (T1), the first counter 90 may be enabled in response to the divided second clock signal DCLK2 and/or perform a counting operation to generate the first code value cd1 in response to the first clock signal CLK1. In FIG. 10, the first code value cd1 generated in the first time period is “101”. The second counter 92 may be enabled in response to the divided second clock signal DCLK2 and/or perform a counting operation to generate the second code value cd2 in response to the input clock signal ICK. In FIG. 10, the second code value cd2 generated in the first time period is “011”. The divider 94 may generate the divided second clock signal DCLK2 having one half (½) frequency of the frequency of the second clock signal CLK2.

During a second time period (T2), the calculator 96 may receive and compare the first code value cd1 and the second code value cd2 to generate the code value CD. The calculator 96 may detect a falling transition (e.g., transition to a low level) of the divided second clock signal DCLK2 to calculate the code value CD. The second time period T2 may be set as a desired time, or alternatively, a time necessary for calculating the code value CD.

During a third time period (T3), the calculator 96 may detect a falling transition of the divided second clock signal DCLK2 to generate the switching control signal scon which may be a pulse signal activated after the time period T2.

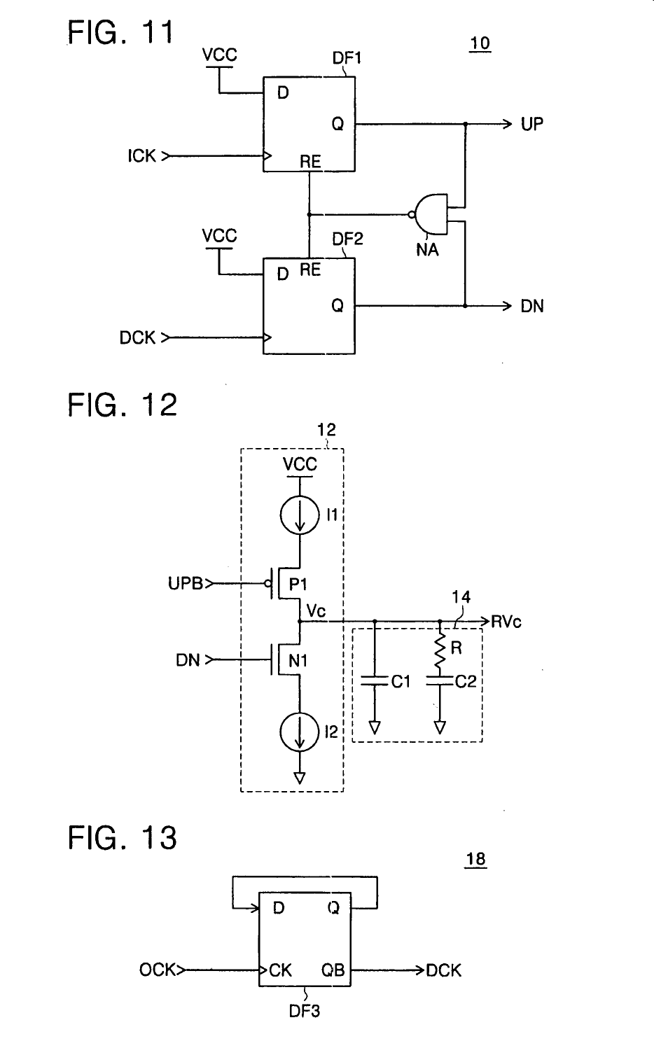

FIG. 11 is a circuit diagram illustrating the phase difference detector 10 of the PLL circuit of FIG. 3. The phase difference detector 10 of FIG. 11 may include D flip flops DF1 and DF2 and/or an NAND gate NA.

Functions of the components of FIG. 11 are explained below.

Each of the D flip flops DF1 and DF2 may receive the power supply voltage VCC through an input D.

The D flip flop DF1 may generate an up signal UP having a high level at a rising edge of the input clock signal ICK and/or may be reset to generate the up signal UP having a low level if an output signal of the NAND gate NA has a low level.

The D flip flop DF2 may generate a down signal DN having a high level at a rising edge of the divided output clock signal DCK and/or may be reset to generate the down signal DN having a low level if the output signal of the NAND gate NA has a low level. The NAND gate NA may generate the up and down signals UP and DN and/or the NAND gate NA may have a low level if both of the up and down signals UP and DN have a high level.

FIG. 12 is a circuit diagram illustrating the charge pump 12 and the loop filter 14 of the PLL circuit of FIG. 3. The charge pump 12 may include supplying and/or discharging constant current sources 11 and 12, a PMOS transistor P1, and/or an NMOS transistor N1, and the loop filter 14 may include capacitors C1 and C2 and/or a resistor R.

Operations of the charge pump 12 and the loop filter 14 are explained below.

If an inverted up signal UPB, for example the up signal UP from the phase difference detector may be inverted, having a low level is applied, the PMOS transistor P1 may be turned on, so that the electric current of the supplying constant current source I1 may be supplied to an output terminal through the PMOS transistor P1, thereby raising the level of the control voltage Vc. The generated control voltage Vc may be filtered by the loop filter 14 to generate the filtered control signal RVc.

On the other hand, if the down signal DN having a high level is applied, the NMOS transistor N1 may be turned on, so that the electric current of the output terminal may be discharged through the NMOS transistor N1 to flow to the discharging constant current source 12, thereby dropping the level of the control voltage Vc. The generated control voltage Vc may be filtered by the loop filter 14 to generate the filtered control signal RVc.

In a locked state, for example in a state where the phase of the input clock signal ICK and a phase of the output clock signal OCK1 are locked, if the inverted up signal UP having a high level and/or the down signal DN having a low level are applied, both the PMOS transistor P1 and the NMOS transistor N1 may be turned off, so that the electric current is not supplied to the output terminal from the supplying constant current source I1, and/or the electric current is not discharged to the discharging constant current source 12 from the output terminal. Accordingly, the level of the control voltage Vc may be maintained “as is.”

FIG. 13 is a circuit diagram illustrating the divider 18 of the PLL circuit of FIG. 3. The divider 18 of FIG. 13 represents a ½ divider which may include a D flip flop DF3. The D flip flop DF3 may have an input terminal D and an inverted output terminal QB.

An operation of the divider of FIG. 13 is explained below.

The D flip flop DF3 may generate the divided output clock signal DCK having one half (½) frequency of the frequency of the output clock signal OCK1 through the inverted output QB terminal Q if the output clock signal OCK1 is applied. For example, an output Q of the D flip flop may be connected to an input D of the D flip flop, and/or the divided output clock signal DCK may be generated from the inverted output QB in response to the output clock signal OCK1.

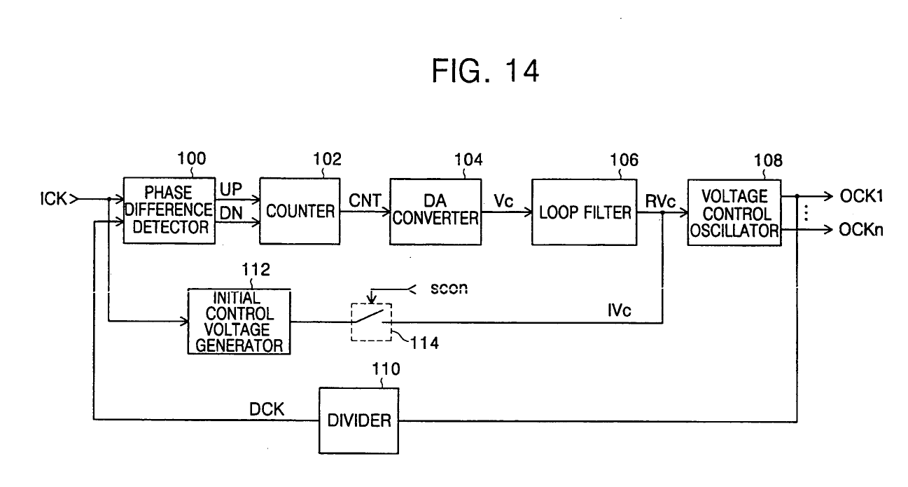

FIG. 14 is a block diagram illustrating a PLL circuit according to another example embodiment. The PLL circuit of FIG. 14 may include a phase difference detector 100, a counter 102, a digital-to-analog (DA) converter 104, a loop filter 106, a voltage control oscillator 108, a divider 110, an initial control voltage generator 112, and/or a switch 114.

Functions of the components of FIG. 14 are explained below.

The phase difference detector 100, the initial control voltage generator 112 and the switch 114 may perform the same functions as those of FIG. 3. The counter 102 may perform an up counting operation in response to the up signal UP or perform a down counting operation in response to the down signal DN to generate a desired, or alternatively, a predetermined-bit digital counting output signal CNT (for example, an i-bit digital counting output signal). The DA converter 104 may convert the digital counting output signal to an analog signal to generate the control voltage Vc. The loop filter 106 may filter the control voltage Vc to generate a filtered control signal RVc. The voltage control oscillator 108 may generate the output clock signals OCK1 to OCKn with the output clock signal OCK1 having the same phase as the input clock signal ICK in response to the voltage level of the filtered control signal RVc. The divider 110 may divide the output clock signal OCK1 to generate the divided output clock signal DCK.

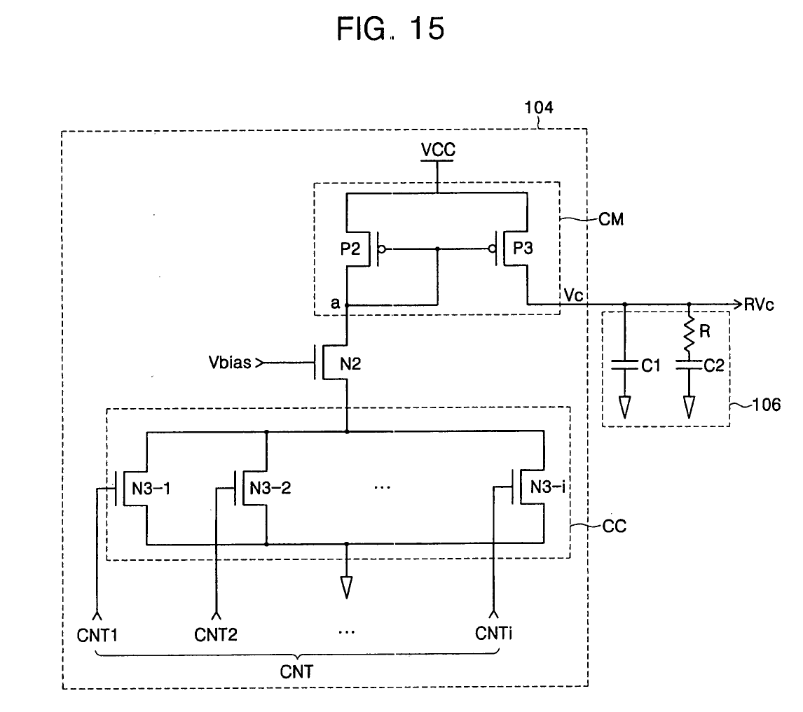

FIG. 15 is a circuit diagram illustrating the DA converter 104 and the loop filter 106 of the PLL circuit of FIG. 14. The DA converter 104 may include a current mirror CM having PMOS transistors P2 and P3, a current adjusting portion CC having NMOS transistors N3-1 to N3-i, and/or an NMOS transistor N2, and/or the loop filter 106 may include capacitors C1 and C2 and/or a resistor R. For example, the current mirror CM may be connected to the current adjusting portion CC by the NMOS transistor N2 and/or the current mirror CM may be connected to the loop filter 106 through the drain of the PMOS transistor P3.

In FIG. 15, Vbias may denote a bias voltage, and CNT1 to CNTi may denote the i-bit digital counting output signal CNT A source of the PMOS transistors P2 and a source of the PMOS transistor P3 of the current mirror CM may be connected to the power supply voltage VCC.

Operations of the DA converter 104 and the loop filter 106 of FIG. 15 are explained below.

If a desired, or alternatively, a predetermined level of the bias voltage Vbias is applied (for example, if the bias voltage Vbias is applied to a gate of the NMOS transistor N2) and all bits of the i-bit digital counting output signal CNT have a high level, the NMOS transistors N3-1 to N3-i may be turned on, so that the electric current flowing through the NMOS transistors N3-1 to N3-i becomes an upper level. Accordingly, a voltage level of a node “a” (for example a voltage of a node between a drain of the NMOS transistor N2, a drain of the PMOS transistor P2, and/or gates of the PMOS transistors P2 and P3) may become a lower level, so that the level of the control voltage Vc (for example, the level of a voltage output from the source of the PMOS transistor P3 in the current mirror CM) becomes an upper level. On the other hand, if all the bits of the i-bit digital counting output signal CNT have a low level, the NMOS transistors N3-1 to N3-i may be turned off. Accordingly, the voltage level of the node “a” becomes an upper level, and/or the level of the control voltage Vc becomes a lower level. Accordingly, the electric current flowing through the NMOS transistors N3-1 to N3-i may be adjusted in response to the i-bit digital counting output signal CNT so that the level of the control voltage Vc and the level of the filtered control signal RVc may vary.

The phase difference detector 100, the voltage control oscillator 108, the divider 110, the initial control voltage generator 112, and the switch 114 of FIG. 14 may have the same configuration as those of FIG. 3.

In above example embodiments, the switch may be turned on in response to the switching control signal scon to transmit the locking control voltage Vco, and/or the switching control signal scon may be generated from the initial control voltage generator 20. However, example embodiments are not limited thereto and the switching control signal scon may be generated if the phase lock loop is powered on.

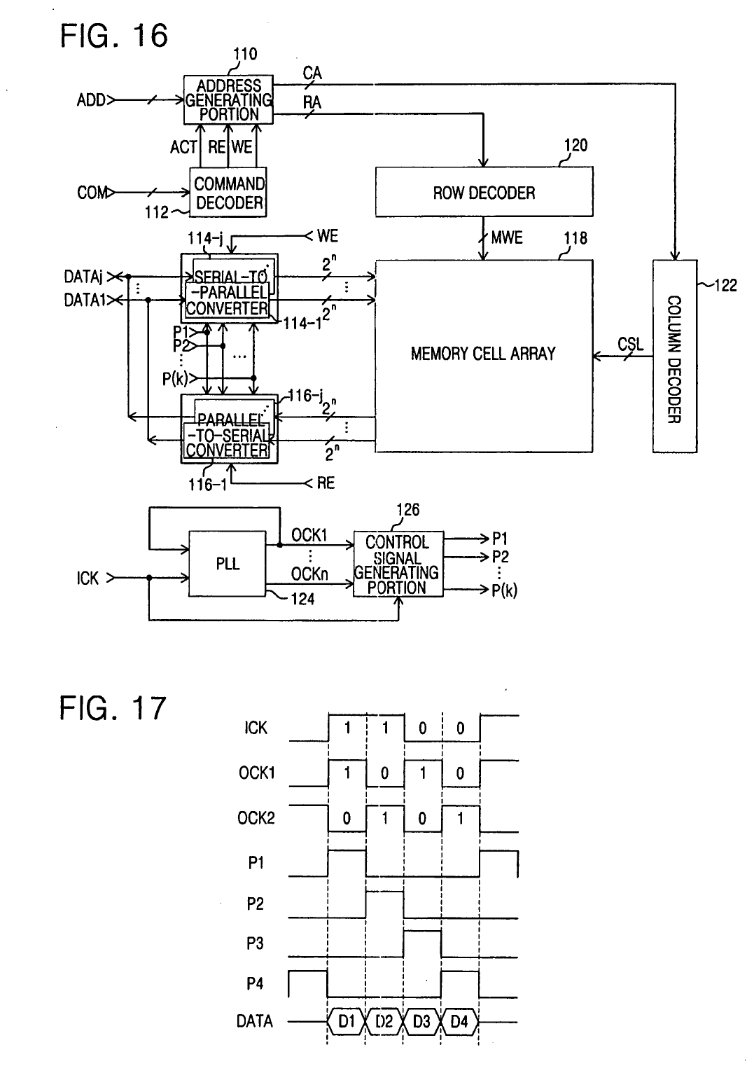

FIG. 16 is a block diagram illustrating a semiconductor device according to an example embodiment. The semiconductor device of FIG. 16 may include an address generating portion 110, a command decoder 112, serial-to-parallel converters 114-1 to 114-j, parallel-to-serial converters 116-1 to 116-j, a memory cell array 118, a row decoder 120, a column decoder 122, a phase locked loop (PLL) 124, and/or a control clock signal generating portion 126. In FIG. 16, the PLL 124 and the control clock signal generating portion 126 may constitute a clock signal generator.

Functions of the components of FIG. 16 are explained below.

The address generating portion 110 may buffer an address ADD applied from an external portion to generate a row address RA in response to an active command ACT and/or buffer the address ADD applied from the external portion to generate a column address CA in response to a read command RE or a write command WE. The command decoder 112 decodes a command signal COM applied from the external portion to generate the active command ACT, the read command RE, and/or the write command WE. The serial-to-parallel converters 114-1 to 114-j may convert serial data DATA1 to DATAj applied through data I/O pins (not shown) into parallel data to generate k-bit parallel data in response to the write command WE and/or control clock signals P1 to P(k), respectively. The parallel-to-serial converters 116-1 to 116-j may convert k-bit parallel data into serial data in response to the read command RE and/or the control clock signals P1 to P(k), respectively. Accordingly, j k-bit serial data may be output through j data I/O pins (not shown), respectively. For example, one parallel data applied through k lines may be serially output bit by bit through one data I/O pin (not shown). The memory cell array 118 may store the j k-bit parallel data into a selected memory cell (not shown) in response to a main word line selecting signal MWE and/or a column selecting signal CSL during the write operation, and/or may output the j k-bit parallel data stored in the selected memory cell (not shown) in response to the main word line selecting signal MWE and/or the column selecting signal CSL during a read operation. The row decoder 120 may decode the row address RA to generate the main word line selecting signal CSL, and/or the column decoder 122 may decode the column address CA to generate the column selecting signal CSL. The PLL 124 may have the same configuration as the PLL of FIG. 3 or the PLL of FIG. 14 of example embodiments. The PLL 124 may calculate the control voltage corresponding to the input clock signal ICK to cause the voltage level of the filtered control signal RVc to become the level of the control voltage at the initial stage, compare the phase of the input clock signal ICK applied from the external portion and the phase of one output clock signal OCK1, and/or perform a phase locking operation between the clock signals ICK and OCK1 to thereby generate the n output clock signals OCK1 to OCKn. The control signal generating portion 126 may receive the input clock signal ICK and the n output clock signals OCK1 to OCKn to generate the k control clock signals P1 to P(k).

FIG. 17 is an example timing diagram illustrating operations of the PLL of the control signal generator of the semiconductor device of FIG. 16 if phase locking is realized between the input clock signal ICK and the output clock signal OCK1.

As shown in FIG. 17, the PLL 124 may generate the output clock signals OCK1 and OCK2 which may have the twice frequency of the input clock signal ICK. The output clock signals OCK1 and OCK2 may have a phase difference of 180°. The control signal generating portion 126 may combine the input clock signal ICK and the output clock signals OCK1 and OCK2 to generate the four control clock signals P1 to P4. The four control clock signals P1 to P4 may have the twice frequency of the input clock signal ICK.

Accordingly, the semiconductor device of FIG. 16 may have a faster locking time because the PLL circuit of FIG. 3 is employed, thereby reducing data errors in the data transmission.

The semiconductor device of FIG. 16 may be configured to generate the control signals P1 to P4 which have different phases and the same phase difference therebetween and/or are activated sequentially by the clock signal generator including the PLL circuit 124 and/or the control clock signal generating portion 126. However, the semiconductor device may be configured such that the clock signal generator need not include the control signal generator 126 and the clock signals generated by the PLL circuit 124 may be used as the control clock signals P1 to P4.

As described above, according to example embodiments, the PLL circuit and/or method, at the initialization period, may compare the number of times that the input clock signal ICK is generated and the number of times that the first clock signal CLK1 is generated in response to the upper locking control voltage during the same period to generate the control voltage level of the control signal applied to the voltage control generator. Accordingly, it may be possible to set the control voltage to the voltage level so that the input clock signal and the output clock signal are locked by one time calculation operation, thereby significantly reducing the locking time.

Accordingly, the semiconductor device having the PLL circuit according to example embodiments may have reduced locking time, thereby reducing data error in the data transmission.

Although example embodiments have been shown and described in this specification and figures, it would be appreciated by those skilled in the art that changes may be made to the illustrated and/or described example embodiments without departing from their principles and spirit.

What is claimed is:

1. A phase locked loop (PLL) circuit, comprising:
a phase difference detecting and control signal generating portion configured to detect a phase difference between an input clock signal and an output clock signal to control a voltage level of a control signal;
a voltage control oscillator configured to vary a frequency of the output clock signal in response to the voltage level of the control signal; and
an initial control voltage generating portion configured to receive the input clock signal, calculate a locking control voltage corresponding to the input clock signal, and cause the voltage level of the control signal to become a level of the locking control voltage for a period of time.

2. The phase locked loop (PLL) circuit of claim 1, wherein the period of time is a period of time from power up.

3. The circuit of claim 1, wherein the initial control voltage generating portion is configured to calculate the locking control voltage based on a number of times that a first clock signal is generated in response to an upper locking control voltage which is an upper voltage level of the control signal and a number of times that the input clock signal is generated during a same time period.

4. The circuit of claim 1, wherein the initial control voltage generating portion is configured to generate a first clock signal in response to an upper locking control voltage which is an upper voltage level of the control signal, a second clock signal in response to a lower locking control voltage which is a lower voltage level of the control signal, and the locking control voltage based on a number of times that the first clock signal is generated and a number of times that the input clock signal is generated during a time period corresponding to a period of the second clock signal.

5. The circuit of claim 4, wherein the initial control voltage generating portion comprises:
a voltage divider configured to divide a power supply voltage to generate a plurality of divided voltages and select one of the plurality of divided voltages in response to a code value as the locking control voltage;
a first clock signal generator configured to generate the first clock signal in response to the upper locking control voltage which is the highest voltage of the plurality of divided voltages;
a second clock signal generator configured to generate the second clock signal in response to the lower locking control voltage which is the lowest voltage of the plurality of divided voltages; and
a code value generator configured to generate the code value based on the number of times that the first clock signal is generated and the number of times that the input clock signal is generated during the time period corresponding to the period of the second clock signal.

6. The circuit of claim 5, wherein the code value generator comprises:
a divider configured to divide the second clock signal to generate a divided second clock signal;
a first counter configured to generate a first count of a number of times the first clock signal is generated in response to the divided second clock signal;
a second counter configured to generate a second count of a number of times the input clock signal is generated in response to the divided second clock signal;
a calculator configured to calculate and output the code value based on the first count and the second count in response to the divided second clock signal.

7. The circuit of claim 6, wherein
the calculator is configured to generate a switching control signal in response to a falling transition of the divided second clock signal, and
the initial control voltage generating portion further includes a switch configured to generate the locking control voltage in response to the switching control signal.

8. The circuit of claim 5, wherein
the voltage control oscillator includes a plurality of first inverters which are dependently connected in the form of a ring,
each of the first and second clock signal generators includes a plurality of second inverters which are equal in number to the plurality of first inverters, and
the plurality of first inverters and the plurality of second inverters have a same delay time.

9. The circuit of claim 5, wherein
the voltage control oscillator includes a plurality of first inverters which are dependently connected in the form of a ring,
each of the first and second clock signal generators includes a plurality of second inverters which are different in number from the plurality of first inverters, and
the plurality of first inverters and the plurality of second inverters have a same delay time.

10. The circuit of claim 5, further comprising:
a divider configured to divide the output clock signal output from the voltage control oscillator to generate at least one divided output clock signal, and wherein
the phase difference detecting and control signal generating portion is configured to detect the phase difference between the input clock signal and the at least one divided output clock signal to control the voltage level of the control signal.

11. The circuit of claim 10, wherein the phase difference detecting and control signal generating portion comprises:
a phase difference detector configured to detect the phase difference between the input clock signal and the at least one divided output clock signal to generate up and down signals; and
a charge pump and loop filter configured to perform an up counting operation to raise the voltage level of the control signal in response to the up signal and perform a down counting operation to lower the voltage level of the control signal in response to the down signal.

12. The circuit of claim 10, wherein the phase difference detecting and control signal generating portion comprises:
a phase difference detector configured to detect the phase difference between the input clock signal and the divided output clock signal to generate up and down signals;
a counter configured to generate a digital counting signal by performing an up counting operation in response to the up signal and performing a down counting operation in response to the down signal; and
a digital-to-analog (DA) converter and loop filter configured to control the voltage level of the control signal in response to the digital counting signal.

13. A semiconductor device, comprising:
the phase locked loop (PLL) circuit of claim 1, the phase locked loop (PLL) circuit configured to generate a plurality of output clock signals which have different phases, the same phase difference therebetween, and the same frequency based on the control signal; and
a data I/O portion configured to receive data applied externally in response to the plurality of output clock signals and output data generated internally to an external portion.

14. The device of claim 13, wherein the initial control voltage generating portion is configured to calculate the locking control voltage based on a number of times that a first clock signal is generated in response to an upper locking control voltage which is an upper voltage level of the control signal and the number of times that the input clock signal is generated during a same time period.

15. The device of claim 13, wherein the initial control voltage generating portion is configured to generate a first clock signal in response to an upper locking control voltage which is an upper voltage level of the control signal, a second clock signal in response to a lower locking control voltage which is a lower voltage level of the control signal, and the locking control voltage based on a number of times that the first clock signal is generated and a number of times that the input clock signal is generated during a time period corresponding to a period of the second clock signal.

16. The device of claim 15, wherein the initial control voltage generating portion comprises:
a voltage divider configured to divide a power supply voltage to generate a plurality of divided voltages and select one of the plurality of divided voltages in response to a code value as the locking control voltage;
a first clock signal generator configured to generate the first clock signal in response to the upper locking control voltage which is the highest voltage of the plurality of divided voltages;
a second clock signal generator configured to generate the second clock signal in response to the lower locking control voltage which is the lowest voltage of the plurality of divided voltages; and
a code value generator configured to generate the code value based on the number of times that the first clock signal is generated and the number of times that the input clock signal is generated during the time period corresponding to the period of the second clock signal.

17. The device of claim 16, wherein the code value generator comprises:
a divider configured to divide the second clock signal to generate a divided second clock signal;
a first counter configured to generate a first count of a number of times the first clock signal is generated in response to the divided second clock signal;
a second counter configured to generate a second count of a number of times the input clock signal is generated in response to the divided second clock signal;
a calculator configured to calculate and output the code value based on the first count and the second count in response to the divided second clock signal.

18. The circuit of claim 17, wherein
the calculator is configured to generate a switching control signal in response to a falling transition of the divided second clock signal, and
the initial control voltage generating portion further includes a switch configured to generate the locking control voltage in response to the switching control signal.

19. The device of claim 16, wherein
the voltage control oscillator includes a plurality of first inverters which are dependently connected in the form of a ring,
each of the first and second clock signal generators includes a plurality of second inverters which are equal in number to plurality of the first inverters, and
the plurality of first inverters and the plurality of second inverters have a same delay time.

20. The device of claim 16, wherein
the voltage control oscillator includes a plurality of first inverters which are dependently connected in the form of a ring,
each of the first and second clock signal generators includes a plurality of second inverters which are different in number from plurality of the first inverters, and
the plurality of first inverters and the plurality of second inverters have the same delay time.

21. The device of claim 16, wherein the PLL circuit further comprises,
a divider configured to divide the output clock signal output from the voltage control oscillator to generate at least one divided output clock signal, and wherein
the phase difference detecting and control signal generating portion is configured to detect the phase difference between the input clock signal and the at least one divided output clock signal to control the voltage level of the control signal.

22. A phase locked loop (PLL) method, comprising:
detecting a phase difference between an input clock signal and an output clock signal to control a voltage level of a control signal;
varying a frequency of the output clock signal in response to the voltage level of the control signal; and
receiving the input clock signal, calculating a locking control voltage corresponding to the input clock signal, and causing the voltage level of the control signal to become a level of the locking control voltage for a period of time.

23. The method of claim 22, wherein the period of time is a period of time from power up.

24. The method of claim 22, wherein the calculating the locking control voltage step comprises:
calculating the locking control voltage based on a number of times that a first clock signal is generated in response to an upper locking control voltage which is an upper voltage level of the control signal and a number of times that the input clock signal is generated during a same time period.

25. The method of claim 22, wherein the calculating the locking control voltage step comprises:
generating a first clock signal in response to an upper locking control voltage which is an upper voltage level of the control signal;
generating a second clock signal in response to a lower locking control voltage which is a lower voltage level of the control signal; and
generating the locking control voltage based on a number of times that the first clock signal is generated and a number of times that the input clock signal is generated during a time period corresponding to a period of the second clock signal.

26. The method of claim 25, wherein the calculating the locking control voltage step further comprises:
dividing a power supply voltage to generate a plurality of divided voltages and selecting one of the plurality of divided voltage in response to a code value as the locking control voltage;
generating the first clock signal in response to the upper locking control voltage which is the highest voltage among the plurality of divided voltages;
generating the second clock signal in response to the lower locking control voltage which is the lowest voltage among the plurality of divided voltages; and
generating the code value based on the number of times that the first clock signal is generated and the number of times that the input clock signal is generated during the time period corresponding to the period of the second clock signal.

27. The method of claim 26, wherein the generating the code value step comprises:
dividing the second clock signal to generate a divided second clock signal;
performing a counting operation to generate a first count of a number of times the first clock signal is generated in response to the divided second clock signal;
performing a counting operation to generate a second count of a number of times the input clock signal is generated in response to the divided second clock signal; and
calculating and outputting the code value based on the first count and the second count in response to the divided second clock signal.

28. A phase locked loop (PLL) circuit, comprising:
a phase difference detecting and control signal generating portion configured to detect a phase difference between an input clock signal and an output clock signal to control a voltage level of a control signal;
a voltage control oscillator configured to vary a frequency of the output clock signal in response to the voltage level of the control signal; and
an initial control voltage generating portion configured to receive the input clock signal, calculate a locking control voltage corresponding to the input clock signal, and cause a voltage level of the control signal to become a level of the locking control voltage until the voltage level of the control signal reaches a threshold.

29. A phase locked loop (PLL) method, comprising:
detecting a phase difference between an input clock signal and an output clock signal to control a voltage level of a control signal;
varying a frequency of the output clock signal in response to the voltage level of the control signal; and
receiving the input clock signal, calculating a locking control voltage corresponding to the input clock signal, and causing the voltage level of the control signal to become a level of the locking control voltage until the voltage level of the control signal reaches a threshold.
